(19) United States
(12) Patent Application Publication
(10) Pub. No.: US 2011/0031608 A1
(43) Pub. Date: Feb. 10, 2011

(54) POWER DEVICE PACKAGE AND METHOD OF FABRICATING THE SAME

(76) Inventors: Tae Hyun KIM, Seoul (KR); Seog Moon Choi, Seoul (KR); Tae Hoon Kim, Gyunggi-do (KR); Bum Sik Jang, Gyunggi-do (KR); Ji Hyun Park, Seoul (KR)

Correspondence Address: BLAKELY SOKOLOFF TAYLOR & ZAFMAN LLP, 1279 OAKMEAD PARKWAY, SUNNYVALE, CA, 94085-4040, US

(21) Appl. No.: 12/562,829

(22) Filed: Sep. 18, 2009

(30) Foreign Application Priority Data
Aug. 6, 2009 (KR) 10-2009-0072440

(51) Int. Cl. H01L 23/48; H01L 21/56

(52) U.S. Cl. 257/692; 438/124; 257/E23.01; 257/E21.502

(57) ABSTRACT

Disclosed is a power device package, which has high heat dissipation performance and includes an anodized metal substrate including a metal plate having a cavity formed on one surface thereof and an anodized layer formed on both the surface of the metal plate and the inner wall of the cavity and a circuit layer formed on the metal plate, a power device mounted in the cavity of the metal plate so as to be connected to the circuit layer, and a resin sealing material charged in the cavity of the metal plate. A method of fabricating the power device package is also provided.

### CROSS REFERENCE TO RELATED APPLICATION

This application claims the benefit of Korean Patent Application No. 10-2009-0072440, filed Aug. 6, 2009, entitled “Power device package and fabricating method of the same”, which is hereby incorporated by reference in its entirety into this application.

### BACKGROUND OF THE INVENTION

1. Technical Field

The present invention relates to a power device package and a method of fabricating the same.

2. Description of the Related Art

A power device, for example, a high-power semiconductor chip selected from among a silicon-controlled rectifier, a power transistor, an insulated gate bipolar transistor, a MOSS transistor, a power rectifier, a power regulator, an inverter, a converter and combinations thereof, is designed to be operated at a voltage of 30˜100 V, or at a voltage above 100 V. Thus, a power device package on which such a high-power semiconductor chip is mounted is required to have high ability to dissipate heat generated from the high power semiconductor chip.

FIG. 1 is a cross-sectional view showing a conventional power device package.

As shown in FIG. 1, the conventional power device package includes a copper plate 20 for transferring heat to a heat sink 25, a DCB (Direct Copper Bonding) circuit substrate 10 formed on the copper plate 20 and having an insulating layer and a circuit layer, and a low power device 13 and a high power device 15 bonded on the DCB circuit substrate 10 using solder 23.

The low power device 13 and the high power device 15 are typically connected to the circuit layer using wires (not shown), and this circuit layer is also connected to a lead frame 27 of a housing wires. As such, the elements including the low power device 13 and the high power device 15 are protected from the external environment using molding resin (not shown).

However, the conventional power device package has the following problems.

First, because the high power device 15 is mounted on one surface of the DCB circuit substrate 10 and the heat sink 25 and the copper plate 20 made of metal having high heat conductivity are attached to the other surface of the DCB circuit substrate 10, the DCB circuit substrate 10 having low heat conductivity blocks transfer of heat, undesirably reducing heat dissipation effects.

Second, the copper plate 20 which is expensive is used to improve heat dissipation performance of the DCB circuit substrate 10 having low heat conductivity, undesirably increasing the fabrication cost and the thickness of the power device package.

Third, because the high power device 15 is bonded on the DCB circuit substrate 10 and the DCB circuit substrate 10 is also bonded on the copper plate 20, two bonding procedures should be performed, and as well, heat dissipation performance may be deteriorated at the bonding interface.

### SUMMARY OF THE INVENTION

Accordingly, the present invention has been made keeping in mind the problems encountered in the related art and the present invention intends to provide a power device package having high heat dissipation performance, and a method of fabricating the same.

Also the present invention intends to provide a power device package which has high heat dissipation performance even without the use of a DCB circuit substrate having low heat conductivity and an expensive copper plate and also which enables reduction of its fabrication cost and thickness, and a method of fabricating the same.

Also the present invention intends to provide a power device package which has a simple configuration thus simplifying a bonding process and reducing the bonding interface that causes deterioration of heat dissipation performance, and a method of fabricating the same.

An aspect of the present invention provides a power device package, including an anodized metal substrate including a metal plate having a cavity formed on one surface thereof and an anodized layer formed on both a surface of the metal plate and an inner wall of the cavity, and a circuit layer formed on the anodized layer; a power device mounted in the cavity of the metal plate so as to be connected to the circuit layer; and a resin sealing material charged in the cavity of the metal plate.

In this aspect, the circuit layer may include an inner circuit layer formed on the inner wall of the cavity, and an outer circuit layer formed on the surface of the metal plate and connected to the inner circuit layer.

Further, a connection member may be formed on the outer circuit layer.

Further, a cover member may be formed on one surface of the metal plate so as to cover the outer circuit layer, and may have a through hole which exposes the outer circuit layer and which has an interconnection portion connected to the outer circuit layer.

Also, a heat sink may be attached to a surface of the anodized metal substrate opposite the surface having the power device.

In this aspect, the metal plate may be made of aluminum or an aluminum alloy, and the anodized layer may include anodic aluminum oxide.

In this aspect, the power device may be connected to the circuit layer using wire bonding or flip chip bonding.

Another aspect of the present invention provides a method of fabricating the power device package, including forming an anodized layer on both a surface of a metal plate having a cavity formed on one surface thereof and an inner wall of the cavity, and then forming a circuit layer on the anodized layer; mounting a power device in the cavity so as to be connected to the circuit layer; and filling the cavity with a resin sealing material.

In this aspect, the circuit layer may include an inner circuit layer formed on the inner wall of the cavity, and an outer circuit layer formed on the surface of the metal plate and connected to the inner circuit layer.

Also, the method may further include forming a connection member on the circuit layer, after the filling the cavity with a resin sealing material.

Also, the method may further include attaching a cover member to one surface of the metal plate, forming a through hole in the cover member so as to expose the outer circuit layer, and forming an interconnection portion in the through hole so as to be connected to the outer circuit layer, after the filling the cavity with a resin sealing material.

Also, the method may further include attaching a heat sink to the other surface of the metal plate, after the filling the cavity with a resin sealing material.

In this aspect, the metal plate may be made of aluminum or an aluminum alloy, and the anodized layer may include anodic aluminum oxide.

In this aspect, in the mounting the power device in the cavity, the power device may be connected to the circuit layer using wire bonding or flip chip bonding.

### BRIEF DESCRIPTION OF THE DRAWINGS

The features and advantages of the present invention will be more clearly understood from the following detailed description taken in conjunction with the accompanying drawings, in which:

FIG. 1 is a cross-sectional view showing a conventional power device package;

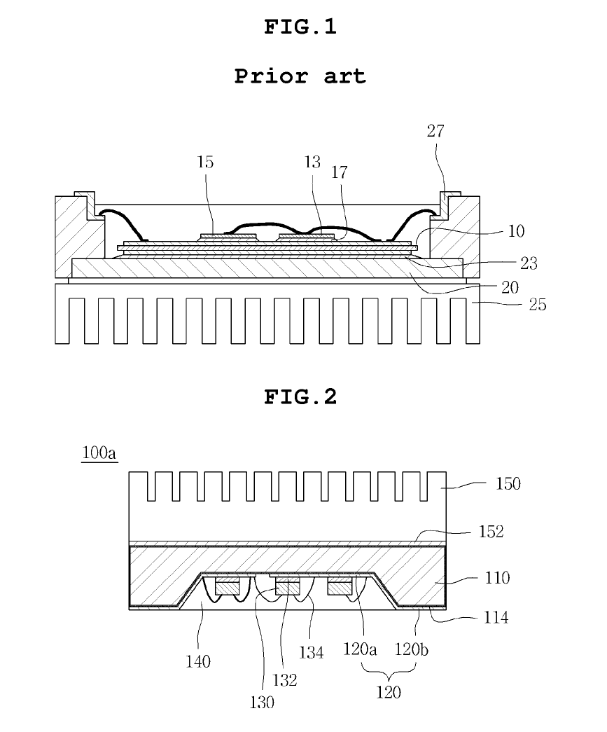

FIG. 2 is a cross-sectional view showing a power device package according to a first embodiment of the present invention;

FIG. 3 is a cross-sectional view showing a power device package according to a second embodiment of the present invention;

FIG. 4 is a cross-sectional view showing a power device package according to a third embodiment of the present invention; and

FIGS. 5 to 12 are cross-sectional views sequentially showing a process of to fabricating the power device package according to the embodiment of the present invention.

### DESCRIPTION OF SPECIFIC EMBODIMENTS

Hereinafter, a detailed description will be given of embodiments of the present invention with reference to the accompanying drawings. Throughout the drawings, the same reference numerals refer to the same or similar elements, and redundant descriptions are omitted. In the description, in the case where known techniques pertaining to the present invention are regarded as unnecessary because they would make the characteristics of the invention unclear and also for the sake of description, the detailed descriptions thereof may be omitted.

Furthermore, the terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept implied by the term to best describe the method he or she knows for carrying out the invention.

### 1^{st} Embodiment

### Power Device Package

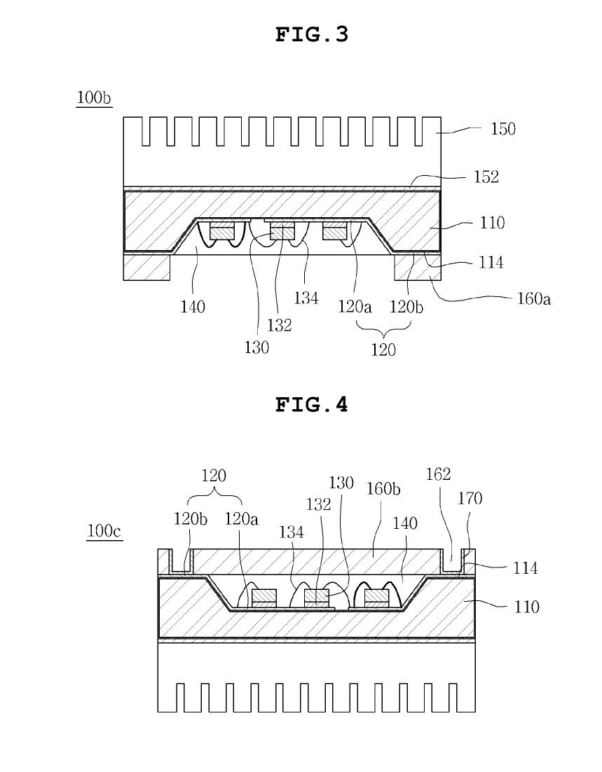

FIG. 2 is a cross-sectional view showing a power device package according to a first embodiment of the present invention. With reference to this drawing, the power device package 100a according to the present embodiment is described below.

As shown in FIG. 2, the power device package 100a according to the present embodiment includes an anodized metal substrate, a power device 130, and a resin sealing material 140.

The anodized metal substrate performs a supporting function and a heat dissipation function, and provides a circuit layer 120 acting as an electrode terminal of the power device 130. The anodized metal substrate is configured such that a cavity 112 for receiving the power device is formed on a metal plate 110, an anodized layer 114 is formed on the entire surface of the metal plate 110 including the inner wall of the cavity 112, and the circuit layer 120 is formed on the anodized layer 114.

The metal plate 110 is made of aluminum (Al) or Al alloy which is relatively inexpensive and easily purchasable and has superior heat transfer properties. Because the metal plate 110 has superior heat transfer properties, it functions as a heat dissipation member for dissipating heat generated from the power device 130, thus obviating a need for an additional heat dissipation member.

The anodized layer 114 may include anodic aluminum oxide (Al₂O₃) having insulation performance and a relatively high heat conductivity ranging from about 10 to 30 W/mK. Because the anodized layer 114 has insulation performance, it enables the formation of the circuit layer 120 on the metal plate 110. Also because the anodized layer 114 may be formed to be thinner than a typical insulating layer, a distance between the metal plate 110 and the power device may be reduced, thereby further increasing heat dissipation performance and making the package thin.

In the present embodiment, the circuit layer 120 is formed in the cavity 112 of the metal plate 110 so as to enable the wire bonding with the power device 130, and is further formed to extend to the outer surface of the metal plate 110. Specifically, the circuit layer 120 includes an inner circuit layer 120a formed on the inner wall of the cavity 112 and an outer circuit layer 120b extending to the surface of the metal plate 110 and connected to the inner circuit layer 120a. As such, the outer circuit layer 120b is connected to an external power source and thus transfers power to the inner circuit layer 120a. Even when the cavity 112 is filled with the resin sealing material 140 and thus the inner circuit layer 120a is not directly connected to the external power source, it is possible to continue supplying power.

The power device 130 may include a high power semiconductor chip selected from among a silicon controlled rectifier, a power transistor, an insulated gate bipolar transistor, a MOSS transistor, a power rectifier, a power regulator, an inverter, a converter and combinations thereof, a diode, or a low power semiconductor chip which is responsible for controlling it.

The power device 130 may be mounted by attaching it in the form of a face-up type to the inner surface of the cavity 112 using a solder material or an epoxy resin so that the pad thereof faces upward, or by attaching it to the inner surface of the cavity 112 using sintering or heat fusion and then connecting the pad of the power device 130 to the inner circuit layer 120a using wires. Although not shown, the power device 130 may be directly mounted on the inner circuit layer 120a through flip chip bonding.

The resin sealing material 140 functions to protect not only the wires 134 but also the power device 130 from the external environment. To this end, the cavity 112 may be filled with the resin sealing material 140, for example, an epoxy molding compound.

Attached to the other surface of the anodized metal substrate is a heat sink 150 for increasing heat dissipation performance using an adhesive 152.

### 2^{nd} Embodiment

### Power Device Package

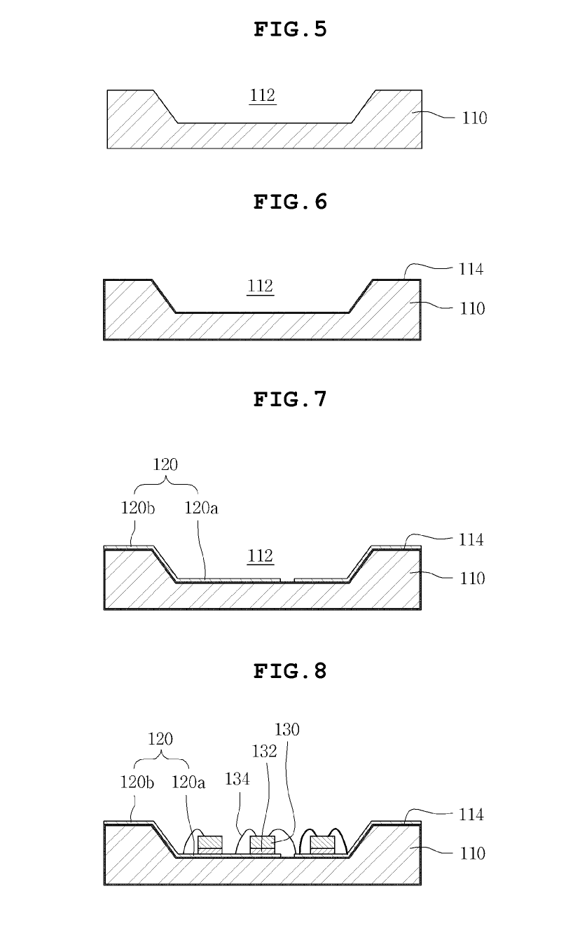

FIG. 3 is a cross-sectional view showing a power device package according to a second embodiment of the present invention. With reference to this drawing, the power device package 100b according to the present embodiment is described below. In the description of the present embodiment, elements which are the same as or similar to those of the previous embodiment are designated by the same reference numerals, and redundant descriptions are omitted.

As shown in FIG. 3, the power device package 100b according to the present embodiment is configured such that a connection member 160a for connecting the package to an external power source or another electronic device is formed on the outer circuit layer 120b formed on one surface of the metal plate 110 and exposed to the outside. As such, the connection member 160a may include a bump such as a solder ball.

### 3^{rd} Embodiment

### Power Device Package

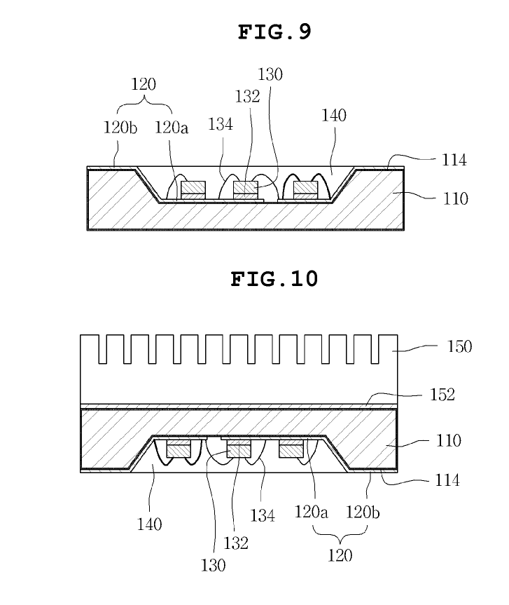

FIG. 4 is a cross-sectional view showing a power device package according to a third embodiment of the present invention. In the description of the present embodiment, elements which are the same as or similar to those of the previous embodiment are designated by the same reference numerals, and redundant descriptions are omitted.

As shown in FIG. 4, the power device package 100c according to the present embodiment is configured such that a cover member 160b is attached to one surface of the metal plate 110 in order to protect the outer circuit layer 120b exposed to the outside. Further, the cover member 160b has a through hole 162 which exposes the outer circuit layer 120b and also which has an interconnection portion 170 formed therein through plating.

As such, in order to reduce the material cost, the cover member 160b may be attached to any region except for the region filled with the resin sealing material 140.

Fabrication of Power Device Package

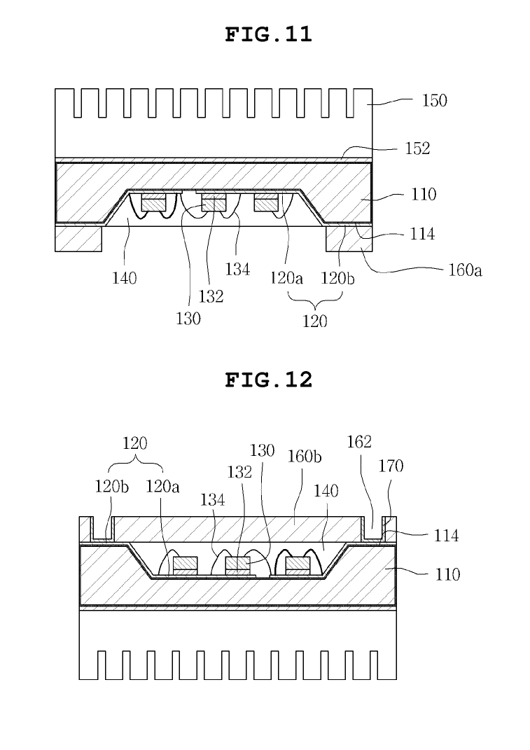

FIGS. 5 to 12 are cross-sectional views sequentially showing a process of fabricating the power device package according to the embodiment of the present invention. Below, the method of fabricating the power device package according to the present embodiment is specified with reference to the above drawings.

As shown in FIG. 5, a metal plate 110 having on one surface thereof a cavity 112 for receiving a power device is prepared.

The cavity 112 may be formed by processing one surface of the metal plate 110 through a chemical or mechanical process (e.g. drilling), or by attaching a metal plate having an additional recess using soldering, arc welding, heat fusion, sintering, etc.

Next, as shown in FIG. 6, an anodized layer 114 is formed on the entire surface of the metal plate 110 including the inner wall of the cavity 112.

The anodized layer 114 may be formed by immersing the metal plate 110 made of Al or Al alloy in an electrolytic solution of boric acid, phosphoric acid, sulfuric acid or chromic acid, applying an anode to the metal plate 110 and applying a cathode to the electrolytic solution. Thereby, formed on the surface of the metal plate 110 is anodic aluminum oxide (Al₂O₃) which has a relatively high heat conductivity ranging from about 10 to 30 W/mK. The anodized layer 114 has insulation performance, thus enabling the formation of a circuit layer thereon, and as well is formed to be thinner than a resin insulating layer and has high heat conductivity, thus contributing to slimness of the anodized metal substrate and improving heat dissipation performance.

Next, as shown in FIG. 7, a circuit layer 120 is formed on the anodized layer 114 of the metal plate 110, thus manufacturing an anodized metal substrate.

As such, the circuit layer 120 may be formed by performing a plating process (electroless plating and electroplating) on the anodized layer 114 thus preparing a plating layer which is then patterned.

The circuit layer 120 includes an inner circuit layer 120a formed on the inner wall of the cavity 112 and an outer circuit layer 120b formed on the surface of the metal plate 110 and electrically connected to the inner circuit layer 120a. As such, the outer circuit layer 120b formed on the surface of the metal plate 110 functions as a mounting pad connected to an external power source, and supplies power to a power device 130 through the inner circuit layer 120a. In the present invention, because the outer circuit layer 120b is formed, even when the cavity 112 is filled with the resin sealing material 140, the connection to the external power source is still possible.

Next, as shown in FIG. 8, the power device 130 is mounted in the cavity 112 so as to be connected to the inner circuit layer 120a.

The power device 130 may be mounted by attaching it in the form of a face-up type to the inner surface of the cavity 112 using a solder material or an epoxy resin so that its pad faces upward, or by attaching it to the inner surface of the cavity 112 using sintering or heat fusion and then connecting the pad of the power device 130 to the inner circuit layer 120a using wires 134. Although not shown, the power device 130 may be directly mounted on the inner circuit layer 120a through flip chip bonding, without the use of the wires 134.

Next, as shown in FIG. 9, the cavity 112 is filled with the resin sealing material 140 for example an epoxy molding compound in order to protect not only the wires 134 but also the power device 130 from the external environment.

The resin sealing material 140 may be charged in the cavity 112 through dispensing, transfer molding, stencil printing or the like.

Next, as shown in FIG. 10, a heat sink 150 is attached to the other surface of the metal plate 110 opposite the surface having the power device 130 mounted thereon.

The heat sink 150 may be attached using an adhesive 152 for example a thermal conductive adhesive, and may have a pin structure so that its surface area is enlarged thus maximizing heat dissipation performance.

Further, as shown in FIG. 11, a connection member 160a for connecting the package to an external power source or another electronic device may be formed on the outer circuit layer 120b formed on one surface of the metal plate 110 and exposed to the outside. The connection member 160a may include a bump such as a solder ball.

Alternatively, as shown in FIG. 12, a cover member 160b may be attached to one surface of the metal plate 110 in order to protect the outer circuit layer 120b exposed to the outside. With the goal of reducing the material cost, the cover member 160b may be formed except for the region filled with the resin sealing material 140.

Further, a through hole 162 may be formed in the cover member 162, and an interconnection portion 170 may be formed through plating in the through hole 162 so as to connect the outer circuit layer 120b to the external power source or another electronic device.

As described hereinbefore, the present invention provides a power device package and a method of fabricating the same. According to the present invention, the power device package has a simple configuration in which a power device is mounted on an anodized metal substrate, and has improved heat dissipation performance.

Also, according to the present invention, an anodized layer which is thinner than a conventional resin insulating layer is formed on a metal plate, thus increasing heat conductivity and realizing slimness of a package.

Also, according to the present invention, the metal plate fulfils the function of a conventional copper plate, and thus there is no need to use the expensive copper plate, thereby decreasing the fabrication cost, simplifying the bonding process and reducing the bonding interface, resulting in improved heat dissipation performance.

Also, according to the present invention, an additional lead frame is not used, thus reducing the fabrication cost of the power device package.

Although the embodiments of the present invention regarding the power device package and the method of fabricating the same have been disclosed for illustrative purposes, those skilled in the art will appreciate that a variety of different modifications, additions and substitutions are possible, without departing from the scope and spirit of the invention as disclosed in the accompanying claims. Accordingly, such modifications, additions and substitutions should also be understood as falling within the scope of the present invention.

What is claimed is:

1. A power device package, comprising:
an anodized metal substrate including a metal plate having a cavity formed on one surface thereof and an anodized layer formed on both a surface of the metal plate and an inner wall of the cavity, and a circuit layer formed on the anodized layer;
a power device mounted in the cavity of the metal plate so as to be connected to the circuit layer; and
a resin sealing material charged in the cavity of the metal plate.

2. The power device package as set forth in claim 1, wherein the circuit layer comprises an inner circuit layer formed on the inner wall of the cavity; and an outer circuit layer formed on the surface of the metal plate and connected to the inner circuit layer.

3. The power device package as set forth in claim 2, wherein a connection member is formed on the outer circuit layer.

4. The power device package as set forth in claim 2, wherein a cover member is formed on one surface of the metal plate so as to cover the outer circuit layer, and has a through hole which exposes the outer circuit layer and which has an interconnection portion connected to the outer circuit layer.

5. The power device package as set forth in claim 1, wherein a heat sink is attached to a surface of the anodized metal substrate opposite the surface having the power device.

6. The power device package as set forth in claim 1, wherein the metal plate comprises aluminum or an aluminum alloy, and the anodized layer comprises anodic aluminum oxide.

7. The power device package as set forth in claim 1, wherein the power device is connected to the circuit layer using wire bonding or flip chip bonding.

8. A method of fabricating a power device package, comprising:
forming an anodized layer on both a surface of a metal plate having a cavity formed on one surface thereof and an inner wall of the cavity, and then forming a circuit layer on the anodized layer;
mounting a power device in the cavity so as to be connected to the circuit layer; and
filling the cavity with a resin sealing material.

9. The method as set forth in claim 8, wherein the circuit layer comprises an inner circuit layer formed on the inner wall of the cavity; and an outer circuit layer formed on the surface of the metal plate and connected to the inner circuit layer.

10. The method as set forth in claim 9, further comprising forming a connection member on the circuit layer, after the filling the cavity with the resin sealing material.

11. The method as set forth in claim 9, further comprising attaching a cover member to one surface of the metal plate, forming a through hole in the cover member so as to expose the outer circuit layer, and forming an interconnection portion in the through hole so as to be connected to the outer circuit layer, after the filling the cavity with the resin sealing material.

12. The method as set forth in claim 8, further comprising attaching a heat sink to the other surface of the metal plate, after the filling the cavity with the resin sealing material.

13. The method as set forth in claim 8, wherein the metal plate comprises aluminum or an aluminum alloy, and the anodized layer comprises anodic aluminum oxide.

14. The method as set forth in claim 8, wherein, in the mounting the power device in the cavity, the power device is connected to the circuit layer using wire bonding or flip chip bonding.
